(19) United States
(12) Patent Application Publication
(10) Pub. No.: US 2022/0014013 A1
(43) Pub. Date: Jan. 13, 2022

(54) Power Electronic Converter with a Ground Fault Detection Unit that Shares a Common Ground with both DC Ports and AC Ports

(71) Applicant: Qingchang Zhong, Willowbrook, IL (US)

(72) Inventor: Qingchang Zhong, Willowbrook, IL (US)

(21) Appl. No.: 17/134,019

(22) Filed: Dec. 24, 2020

(30) Foreign Application Priority Data
Jul. 7, 2020 (GB) 2010378.4

(51) Int. Cl. H02H 7/122; H02M 1/00; G01R 31/52

(52) U.S. Cl. CPC H02H 7/122; G01R 31/52; H02M 1/0009

(57) ABSTRACT

This invention discloses a power electronic converter that streamlines the detection, monitoring, and protection of ground faults. The converter has at least one DC leg with each having a DC port and a first DC bus, at least one AC leg with each having an AC port and a second DC bus, at least one DC-bus capacitor, a ground-fault detection unit, and a Protective Earth terminal that is connected to the earth. The DC port(s). AC port(s), and the ground-fault detection unit are connected together to share a commons ground, which is also the neutral line of the AC ports. The first DC bus(es) of the DC port(s) and the second DC bus(es) of the AC port(s) are connected together to form a converter DC bus with the DC-bus capacitor(s) connected to it. The ground-fault detection unit, connected between the common ground and the Protective Earth terminal, consists of a current sensor and a neutral ground resistor connected in series, together with a voltage sensor to measure the voltage between the Protective Earth terminal and the common ground. When the voltage of the Protective Earth terminal with respect to the common ground exceeds a certain value or when the current flowing through the ground-fault detection unit exceeds a certain value, a visual or audio warning signal is generated to warn the presence of a ground fault. A Residual Current Circuit Breaker or a Ground Fault Circuit Breaker can be connected to the AC port(s) to disconnect the converter in case of ground faults. Possible applications include any field that adopts power electronic converters that converts electricity between DC and AC, e.g., in wind power, solar power, storage systems, home appliances, IT equipment, motor drives, electric vehicles, more-electric aircraft, and all-electric ships.

### CROSS-REFERENCE TO RELATED APPLICATIONS

This nonprovisional patent application claims the benefit of and priority under 35 U.S. Code 119 (b) to U.K. Patent Application No. GB2010378.4 filed on Jul. 7, 2020, entitled “Power Electronic Converter with a Ground Fault Detection Unit that Shares a Common Ground with both DC Ports and AC Ports”, the contents of which are all hereby incorporated by reference herein in its entirety.

### TECHNICAL FIELD

This invention discloses a power electronic converter that streamlines the detection, monitoring, and protection of ground faults. Possible applications include any field that adopts power electronic converters to convert electricity between DC and AC, e.g., in wind power, solar power, storage systems, home appliances, IT equipment, motor drives, electric vehicles, more-electric aircraft, and all-electric ships.

### BACKGROUND

Due to the rapid growth of global economy, the demand for electricity is constantly increasing, leading to energy crisis and environmental issues. To deal with such problems, more and more distributed generators, such as wind and solar farms, are being utilized. The number of power electronic converters being used is rapidly increasing. This presents great challenges to the safety of equipment and personnel, in particular, when ground faults occur.

A ground fault is an unintentional contact between an energized conductor and ground or equipment frame. Because of insulation breakdown and other reasons, ground faults happen frequently. If a proper protection system is in place, the consequences of a ground fault can be as simple as a shutdown. However, without proper protection in place, it could lead to large currents, arcing, fire, electrical shock, equipment damage, or even fatalities. For example, there have been quite a few reports on fire incidents caused by rooftop solar.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

This invention discloses a power electronic converter that streamlines the detection, monitoring, and protection of ground faults.

### BRIEF DESCRIPTION OF THE DRAWINGS

The accompanying figures further illustrate the disclosed embodiments and, together with the detailed description of the disclosed embodiments, serve to explain the principles of the present invention.

FIG. 1 illustrates a prior art single-phase fill-bridge power electronic converter.

FIG. 2 illustrates an example of the disclosed power electronic converter with a built-in ground-fault detection unit that shares a common ground with both DC ports and AC ports.

FIG. 3 illustrates four different options for DC legs.

FIG. 4 illustrates an embodiment of the present invention applied to a storage system.

FIG. 5 illustrates an embodiment of the present invention applied to a PV-storage system.

FIG. 6 illustrates an embodiment of the present invention applied to a single-phase back-to-back power electronic system.

FIG. 7 illustrates an embodiment of the present invention applied to a single-phase back-to-back power electronic system with a battery storage system on the DC port.

FIG. 8 illustrates an embodiment of the present invention applied to a three-phase back-to-back power electronic system.

FIG. 9 illustrates an embodiment of the present invention applied to a three-phase back-to-back power electronic system with a battery storage system on the DC port.

### DETAILED DESCRIPTION

The particular values and configurations discussed in these non-limiting examples can be varied and are cited merely to illustrate at least one embodiment and are not intended to limit the scope thereof.

The embodiments will now be described more fully hereinafter with reference to the accompanying drawings, in which illustrative embodiments of the invention are shown. The embodiments disclosed herein can be embodied in many different forms and should not be construed as limited to the embodiments set forth herein: rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a,” “an.” and “the” are intended to include the plural forms as well, unless the context clearly indicates otherwise. It will be further understood that the terms “comprises” and/or “comprising.” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Subject matter will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms such as “and,” “or.” or “and/or” as used herein may include a variety of meanings that may depend at least in part upon the context in which such terms are used. Typically, “or” if used to associate a list, such as A. B, or C, is intended to mean A. B, and C, here used in the inclusive sense, as well as A, B, or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a.” “an.” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

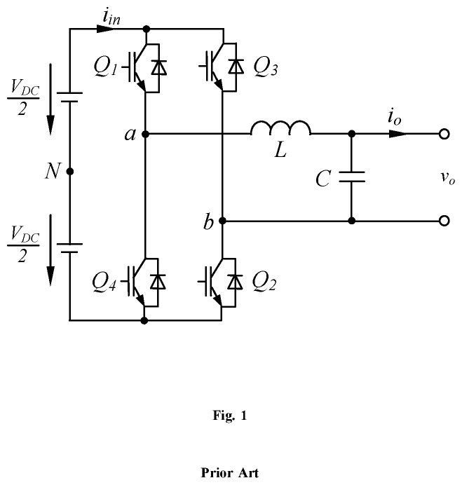

FIG. 1 illustrates a conventional single-phase PWM-controlled converter. It can be operated as a rectifier if an AC supply is connected to υₒ or as an inverter if a DC supply V_{DC} is connected to the DC bus. The DC-bus voltage is split into two V_{DC}/2 with the mid-point denoted as N. It uses four power semiconductor devices Q₁˜Q₄. The devices on the same leg are operated complementarily so that the voltage υ_{ab} is pulse-width-modulated with the fundamental component equal to the desired voltage. The inductor L and the capacitor C are used to filter out switching ripples. For easy reference, the conversion leg that consists of switches Q₁ and Q₄, the inductor L and the capacitor C is denoted as an AC leg. It has a DC bus with voltage V_{DC} and an AC port with voltage υₒ.

Apparently, the DC bus and the AC port in a conventional bridge converter do not share a common ground.

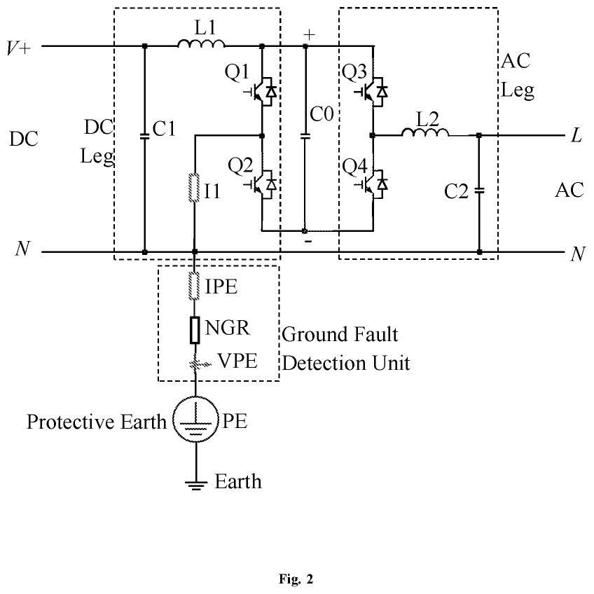

FIG. 2 illustrates an example of the disclosed power electronic converter. It consists of a DC leg with a DC port and a DC bus, an AC leg with an AC port and a DC bus, and a Ground-Fault Detection Unit connected to the Protective Earth terminal PE of the converter, which is connected to the earth. The DC port, the AC port and the Ground-Fault Detection Unit share a common ground N.

The AC leg consists of two sets of power semiconductor devices Q₃ and Q₄ connected in series with a positive terminal (+) and a negative terminal (−) to form a DC bus and with the connected terminals of the two sets of power semiconductor devices connected to the AC port through an inductor L2. A capacitor C2 is connected in parallel with the AC port with terminals L and N.

The DC leg consists of two sets of power semiconductor devices Q₁ and Q₂ connected in series with a positive terminal (+) and a negative terminal (−) to form a DC bus and with the connected terminals of the two sets of power semiconductor devices connected to the common ground N through a current sensor I1. An inductor L1 is connected between the positive terminal (+) of the DC bus of the DC leg and the terminal V+ of the DC port that is not the common ground N. A capacitor C1 is connected in parallel with the DC port.

The DC bus of the DC leg and the DC bus of the AC leg are connected together to form the converter DC bus with a DC-bus capacitor C0 connected to it. The DC-bus capacitor can be a single capacitor or multiple capacitors connected in series-parallel connection.

The Ground-Fault Detection Unit consists of a current sensor IPE and a neutral-ground resistor NGR connected in series between the Protective Earth terminal PE and the common ground N, together with a voltage sensor VPE to measure the voltage between the Protective Earth terminal PE and the common ground N. When the current measured by the current sensor IPE exceeds a certain value, a visual or audio warning signal can be generated to warn that there is a ground fault. Moreover, When the voltage measured by the voltage sensor VPE exceeds a certain value, a visual or audio warning signal can be generated to warn that there is a ground fault. The current signal measured by the current sensor IPE and the voltage signal measured by the voltage sensor VPE can be used to cross-validate the sensors IPE and VPE. As a result, any faults in the sensors can be detected, enhancing the reliability of detecting ground faults.

Each set of power semiconductor devices can have a single device or multiple devices connected in parallel-series connection. Different power semiconductor devices, such as MOSFET and IGBT, can be adopted. They can be normal silicon devices or the emerging wide bandgap devices.

The disclosed power electronic converter is grounded because the current-carrying conductor N is connected to the earth through the Protective Earth terminal PE. The DC side and the AC side of the power electronic converter share a common ground, which is effectively the earth because the voltage V_{PE} dropped on the Ground-Fault Detection Unit is negligible during normal operation. As a result, both the common-mode voltage and the leakage current of the convener are small.

The neutral-ground resistor NGR can be selected to limit the ground-fault current that flows through the Ground-Fault Detection Unit when there is a ground fault. This makes it possible to continuously monitor ground faults in an economic way. A Residual Current Circuit Breaker (RCCB) or a Ground Fault Circuit Breaker (GFCB), which is not shown in FIG. 2 for simplicity, can be connected to the AC port(s) to disconnect the converter in case of ground faults. For additional protection, an RCCB/GFCB with overload protection can be adopted.

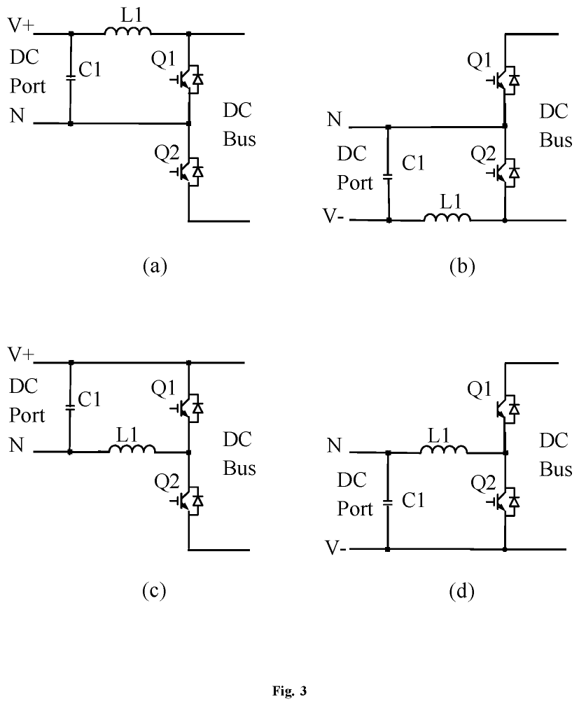

The DC leg and the AC leg shown in FIG. 2 can be replaced with other appropriate topologies, respectively. For example. FIG. 3 shows four different types of DC legs, with the one adopted in FIG. 2 listed in FIG. 3(a), with the current sensor omitted. For the DC leg shown in FIG. 3(b), the DC port takes the lower part of the DC bus voltage V₋ while still using the connected terminals of the two power semiconductor devices as the neutral point N. It is symmetric to the one shown in FIG. 3(a). For the DC leg shown in FIG. 3(c), the inductor L1 in FIG. 3(a) is moved to the neutral line and the DC port shares the same positive terminal with the DC bus. For the DC leg shown in FIG. 3(d), it is symmetric to the DC leg shown in FIG. 3(c) and the DC port shares the same negative terminal with the DC bus.

It is worth noting that although only one DC leg and only one AC leg are shown in FIG. 2, it is possible to have multiple DC legs and multiple AC legs connected in parallel, respectively, if needed.

The disclosed invention can be applied to many different applications. Some of them are briefly described below.

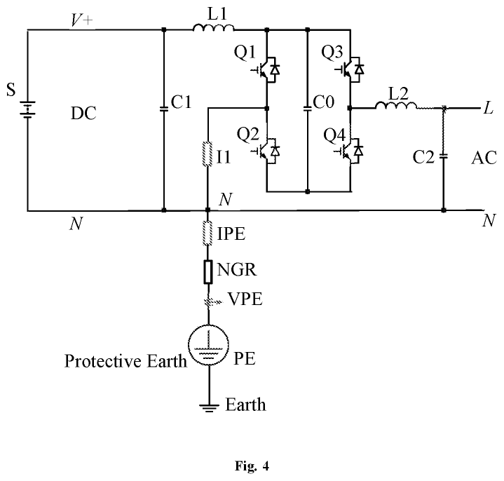

FIG. 4 illustrates an embodiment of the present invention applied to a storage system, where a storage unit S is connected to the DC port between terminals V+ and N. The converter can be controlled to charge and discharge the storage unit S, while streamlining the detection, monitoring, and protection of ground faults. Note that the storage unit S shares the same common ground N.

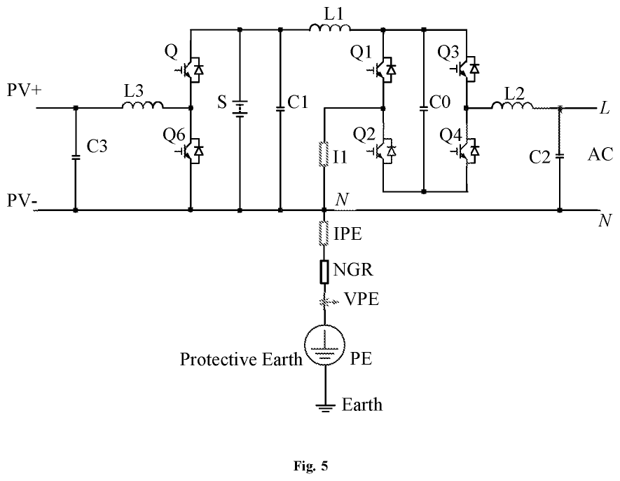

FIG. 5 illustrates an embodiment of the present invention applied to a PV-storage system. Another DC leg is added to connect a string of PV panels between PV+ and PV− with the DC bus of the added DC leg connected to the storage unit S in the system shown in FIG. 4. This makes it a PV-storage system. Such a DC leg is called a PV leg. Of course, more than one PV leg can be added if needed. If there is a ground fault, then the ground-fault current returns through the neutral line and the Ground-Fault Detection Unit. The converter can detect the ground fault by measuring the current with the current sensor IPE and measuring the voltage V_{PF}, with the voltage sensor VPE. If a Residual Current Circuit Breaker (RCCB) or a Ground Fault Circuit Breaker (GFCB) is connected to the AC port(s), then it can detect the ground-fault current as well and disconnect the converter when there is a ground fault.

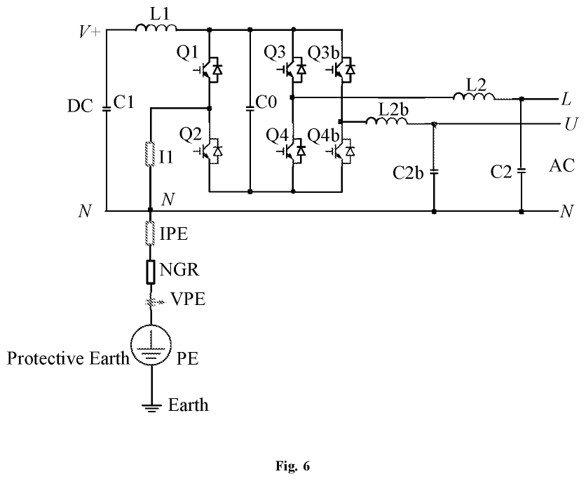

FIG. 6 illustrates an embodiment of the present invention applied to a single-phase back-to-back power electronic system. It contains two AC legs, which can be operated at different phases, different frequencies, and/or different voltages. The DC leg maintains a stable voltage so that the two AC ports can share the same neutral point N.

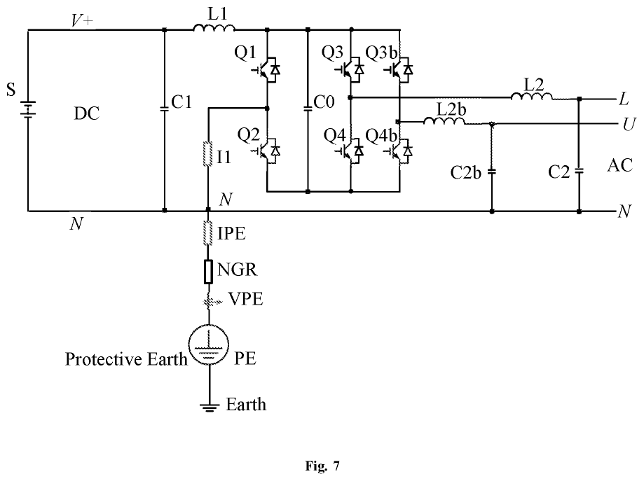

FIG. 7 illustrates an embodiment of the present invention applied to a single-phase back-to-back power electronic system with a battery storage system on the DC port. A storage unit S is added to the single-phase back-to-back power electronic system shown in FIG. 6. This makes it possible to buffer the real power difference between the two AC ports.

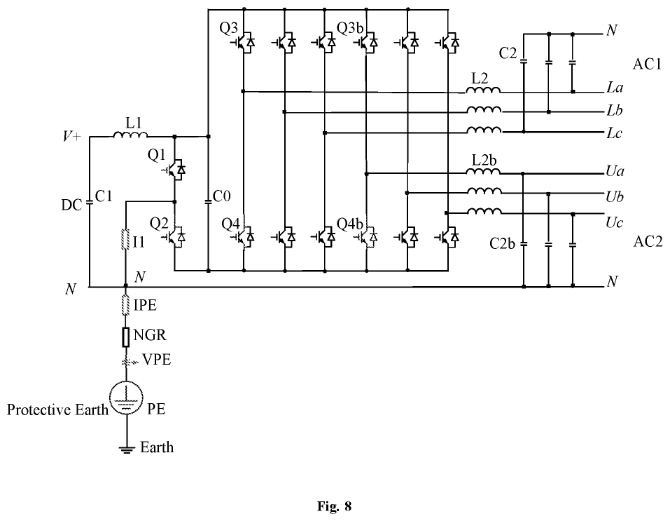

FIG. 8 illustrates an embodiment of the present invention applied to a three-phase back-to-back power electronic system. The system contains a total of six AC legs, which can be operated as a three-phase back-to-back system with a common neutral line. Possible applications include wind power etc.

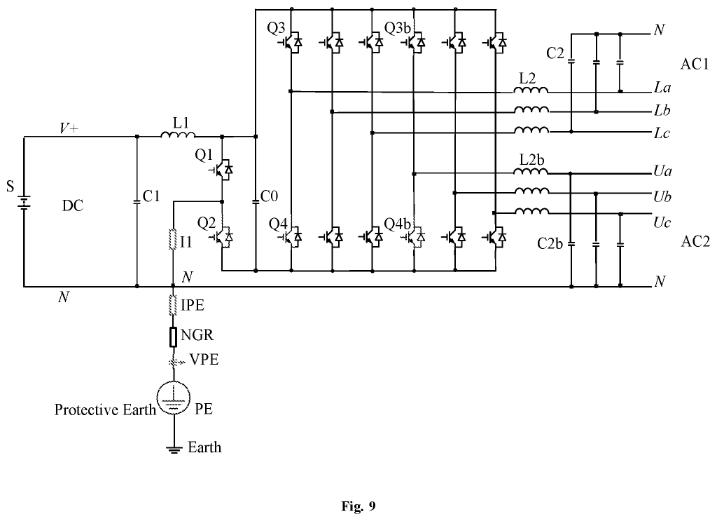

FIG. 9 illustrates an embodiment of the present invention applied to a three-phase back-to-back power electronic system with a battery storage system S added on the DC port. This makes it possible to buffer the real power difference between the two AC sides.

It will be appreciated that variations of the above-disclosed and other features and functions, or alternatives thereof, may be desirably combined into many other different systems or applications. It will also be appreciated that various presently unforeseen or unanticipated alternatives, modifications, variations or improvements therein may be subsequently made by those skilled in the art, which are also intended to be encompassed by the following claims.

What is claimed is:

1) A power electronic converter, comprising:
at least one DC leg, each having a DC port and a first DC bus;
at least one AC leg, each having an AC port and a second DC bus;
at least one DC-bus capacitor;
a ground-fault detection unit; and a Protective Earth terminal that is connected to the earth;
wherein the DC port(s), the AC port(s), and the ground-fault detection unit are connected to a common ground;
wherein the first DC bus(es) of the DC port(s) and the second DC bus(es) of the AC port(s) are connected together to form a converter DC bus with the DC-bus capacitor(s) connected to it;
wherein the common ground is a neutral line of the AC port(s); and
wherein the ground-fault detection unit is connected between the common ground and the Protective Earth terminal.

2) The converter as claimed in claim 1, wherein the ground-fault detection unit consists of a first current sensor and a neutral ground resistor connected in series, together with a voltage sensor that measures the voltage between the Protective Earth terminal and the common ground.

3) The converter as claimed in claim 1, wherein each DC leg consists of two sets of power semiconductor devices connected in series with a positive terminal and a negative terminal to form the first DC bus and with the connected terminals of the two sets of power semiconductor devices connected to the common ground through a second current sensor, a first inductor connected between a terminal of the first DC bus and a terminal of the DC port that is not the common ground, and a first capacitor connected in parallel with the DC port.

4) The converter as claimed in claim 1, wherein each AC leg consists of two sets of power semiconductor devices connected in series with a positive terminal and a negative terminal to form the second DC bus and with the connected terminals of the two sets of power semiconductor devices connected to the AC port through a second inductor, and a second capacitor connected in parallel with the AC port.

5) The converter as claimed in claim 1, wherein the AC port(s) are connected to a Residual Current Circuit Breaker or a Ground Fault Circuit Breaker.

6) The converter as claimed in claim 2, wherein the neutral ground resistor is set to limit the current flowing through it below a certain level when there is a ground fault.

7) The converter as claimed in claim 2, wherein the first current sensor measures the current flowing through it and a visual or audio warning signal is generated when the current flowing through it exceeds a certain value.

8) The converter as claimed in claim 2, wherein the voltage sensor measures the voltage of the Protective Earth terminal with respect to the common ground and a visual or audio warning signal is generated when the voltage of the Protective Earth terminal with respect to the common ground exceeds a certain value.

9) The converter as claimed in claim 2, wherein the current signal measured by the first current sensor and the voltage signal measured by the voltage sensor are used to cross-validate the first current sensor and the voltage sensor.

10) The converter as claimed in claim 1, wherein each DC leg consists of two sets of power semiconductor devices connected in series with a positive terminal and a negative terminal to form the first DC bus and with the connected terminals of the two sets of power semiconductor devices connected to the common ground through a third current sensor in series with a third inductor, and a third capacitor connected in parallel with the DC port that has one terminal connected to the common ground and the other terminal connected to a terminal of the first DC bus.

11) A method to streamline the detection, monitoring, and protection of ground faults for power electronic converters, comprises the steps of:
building a power electronic converter with
at least one DC leg, each having a DC port and a first DC bus;
at least one AC leg, each having an AC port and a second DC bus;
at least one DC-bus capacitor;
a ground-fault detection unit; and
a Protective Earth terminal that is connected to the earth:
connecting the DC port(s), the AC port(s), and the ground-fault detection unit to a common ground, which is the neutral line of the AC port(s);
connecting the first DC bus(es) of the DC port(s) and the second DC bus(es) of the AC port(s) together to form a converter DC bus with the DC-bus capacitor(s) connected to it;
building a ground-fault detection unit via putting a current sensor and a neutral ground resistor in series and a voltage sensor to measure the voltage between terminals of the ground-fault detection unit;
connecting the ground-fault detection unit between the common ground and the Protective Earth terminal;
selecting a proper value for the neutral ground resistor to limit the current flowing through it below a certain level when there is a ground fault; and
installing a Residual Current Circuit Breaker or a Ground Fault Circuit Breaker at the AC port(s).
